(19) United States
(12) Patent Application Publication
(10) Pub. No.: US 2026/0344006 A1
(43) Pub. Date: Oct. 29, 2026

(54) SEMICONDUCTOR STRUCTURE AND METHOD FOR FORMING THE SAME

(71) Applicant: Taiwan Semiconductor Manufacturing Co., Ltd., Hsinchu (TW)

(72) Inventors: Szu-Chien WU, Hsinchu (TW); Chun-Yuan CHEN, Hsinchu (TW); Huan-Chieh SU, Hsinchu (TW); Chih-Hao WANG, Hsinchu (TW)

(73) Assignee: Taiwan Semiconductor Manufacturing Co., Ltd., Hsinchu (TW)

(21) Appl. No.: 19/307,891

(22) Filed: Aug. 22, 2025

Related U.S. Application Data
(60) Provisional application No. 63/796,202, filed on Apr. 28, 2025.

(51) Int. Cl. H10D 84/01; H10D 64/23; H10D 84/83

(52) U.S. Cl. CPC H10D 84/0149; H10D 64/251; H10D 84/013; H10D 84/832

(57) ABSTRACT

An integrated circuit includes a trench isolation structure between two semiconductor fins. A first source/drain region of a first transistor is formed in the first semiconductor fin. A second source/drain region of a second transistor is formed in the second semiconductor fin adjacent to the first source/drain region. A first source/drain contact is formed over the first source/drain region includes a single metal layer. A second source/drain contact is formed over the second source/drain region and includes a stack of two metal layers. An upper metal layer of the second source/drain contact extends laterally over an edge of a lower metal layer of the second source/drain contact and overlies the trench isolation structure.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-20 are cross-sectional, perspective views, and top views of an integrated circuit at various stages of processing, in accordance with some embodiments.

FIG. 21 is a flow diagram of a method of manufacturing an integrated circuit, in accordance with some embodiments.

FIG. 22 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In accordance with some embodiments, active regions are implemented in conjunction with semiconductor fins that extend in a first lateral direction (e.g., X direction). Trench isolation structures extend in the first lateral direction alongside and between adjacent semiconductor fins. Gate regions extend across the semiconductor fins and the trench isolation structures in a second lateral direction (e.g., Y direction). Source/drain regions of transistors are formed in the semiconductor fins, with stacked channels of a transistor extending between adjacent source/drain regions in the X direction. The stacked channels are formed from the semiconductor fins and are positioned where the gate regions cross the active region. At a layout level, source/drain contact metals extend in the second lateral direction. Source/drain contact cut regions extend in the first lateral direction above the trench isolation structures. Where a source/drain contact cut region crosses a source/drain contact region, the source/drain contact metals are removed or are not formed so that source/drain contacts of adjacent transistors can be electrically isolated from each other.

Embodiments of the present disclosure provide source/drain contacts that enable continued scaling of active region pitches and trench isolation structure dimensions. In some embodiments, the source/drain contact cut regions do not overlap the semiconductor fins but are instead located entirely over the trench isolation structures. Embodiments of the present disclosure enable selected source/drain contacts to be formed using a stack of two source/drain contact metals. More particularly, when adjacent source/drain regions of two transistors formed in different semiconductor fins are to be electrically isolated from each other and both are to be contacted by respective conductive vias, one of the source/drain contacts includes the stack of two metals, while the other includes only one source/drain contact metal. In the stack of two source/drain contact metals, the higher metal overlaps an edge of the lower metal such that the higher metal is closer to the source/drain contact of the adjacent transistor across the trench isolation structure. This layout and structure enables further scaling of active region pitches, increased density of transistor formation, better coverage of source/drain silicides by source/drain contact regions, reduced time-dependent dielectric breakdown, and overall better device performance. Embodiments of the present disclosure further provide better functioning integrated circuits and increased wafer yields.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

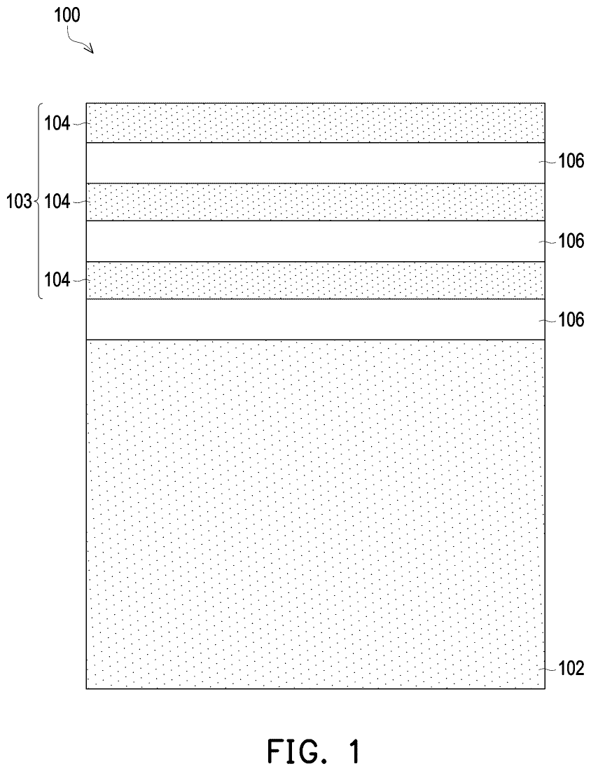

FIGS. 1-17 are cross-sectional, perspective, and top views of an integrated circuit 100 fabricated in accordance with some embodiments of the present disclosure. The fabrication process results in a plurality of transistors 101, as will be described in further detail below.

FIG. 1 is a cross-sectional view of the integrated circuit 100 at an intermediate stage of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. In the example of FIG. 1 the stack 103 includes three semiconductor layers 104 and three sacrificial semiconductor layers 106. However, in practice, different numbers of semiconductor layers 104 and sacrificial semiconductor layers 106 can be utilized without departing from the scope of the present disclosure.

As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In

In some embodiments, the semiconductor layers 104 may be formed of a first semiconductor material, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In one example, the semiconductor layers 104 are silicon and the sacrificial semiconductor layers 106 are silicon germanium. In some embodiments, the sacrificial semiconductor layers 106 have a concentration of germanium between 10% and 50%, though other concentrations can be utilized without departing from the scope of the present disclosure. This enables the sacrificial semiconductor layers 106 to be selectively etchable with respect to the semiconductor layers 104. Other materials and concentrations can be utilized without departing from the scope of the present disclosure.

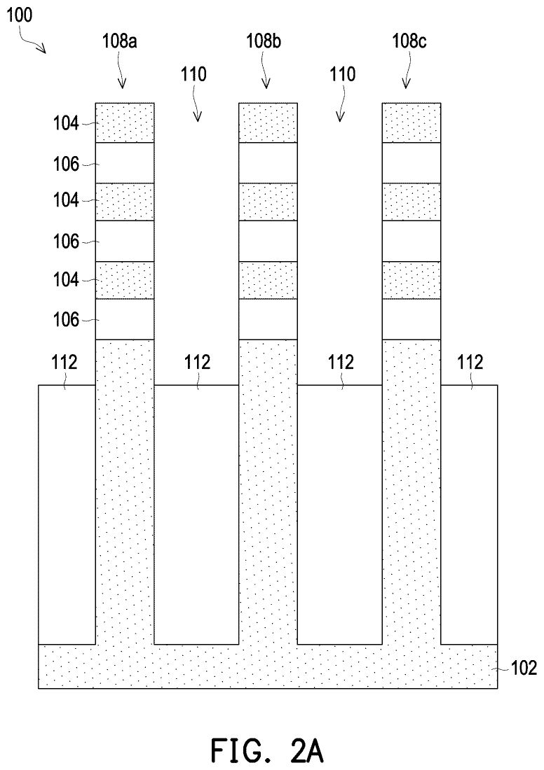

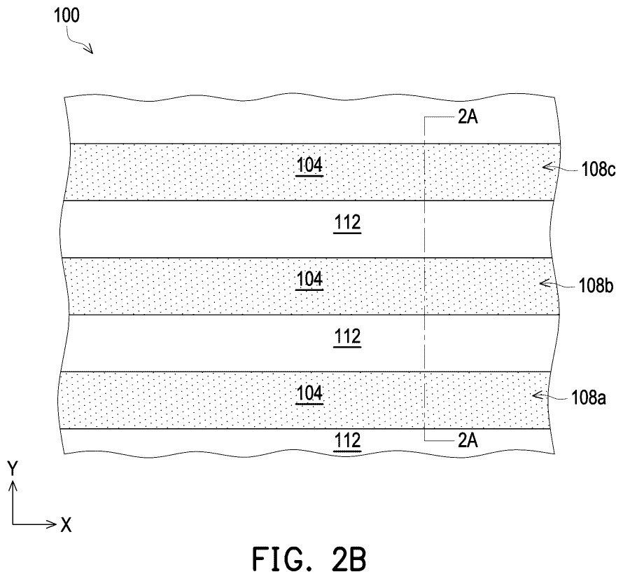

FIG. 2A is a cross-sectional view of the integrated circuit 100, in accordance with some embodiments. FIG. 2B is a top view of the integrated circuit 100 at the stage of processing shown in FIG. 2A, in accordance with some embodiments. The cross-sectional view of FIG. 2A is taken along cut lines 2A from FIG. 2B.

In FIG. 2A, a plurality of semiconductor fins 108a-c have been formed from the stack 103. In the following discussion, some reference numbers include a suffix “a”, “b”, or “c”. The suffixes may be omitted when reference is not particular to a specific single structure. For example, the semiconductor fins 108a-c may be referred to as simply semiconductor fins 108 when reference is generic to each of the semiconductor fins.

The semiconductor fins 108 are formed by forming trenches 110 in the stack 103 and in the substrate 102. Though not shown in FIG. 1, a hard mask layer is first formed and patterned on the stack 103. The trenches 110 are be formed with an anisotropic etching process that etches in the downward direction in the presence of the patterned hard mask. The etching process defines semiconductor fins 108 by forming trenches 110 through the sacrificial semiconductor layers 106, the semiconductor layers 104, and the substrate 102. The semiconductor fins 108 extend in the X direction and are separated from each other in the Y direction by the trenches 110.

The semiconductor fins 108 each correspond to an active area or an active region of the integrated circuit 100. Each active region corresponds to location in which the source/drain and channel regions of transistors are formed. The semiconductor fin 108a corresponds to a first active region. The semiconductor fin 108b corresponds to a second active region. The semiconductor fin 108c corresponds to a third active region. In some embodiments, the substrate 102 of each semiconductor fin corresponds to a doped well region.

In FIGS. 2A and 2B, shallow trench isolation structures 112 have been formed by depositing a dielectric material in the trenches 110 between fins 108. FIG. 2A illustrates the shallow trench isolation structures 112 as a single layer of dielectric material. However, in practice, a plurality of dielectric layers can be utilized to form the trench isolation structures 112. The dielectric layer(s) may be deposited by chemical vapor deposition (CVD), atomic layer deposition (ALD), physical vapor deposition (PVD), or other suitable deposition processes. In an exemplary embodiment, the dielectric material of the trench isolation structures 112 includes silicon oxide. However, the dielectric material can include SiN, SiCN, SiOC, SiOCN, or other dielectric materials without departing from the scope of the present disclosure.

After deposition of the dielectric material of the trench isolation structure 112, an etch-back process has been performed to recess the top of the shallow trench isolation structures 112 below the lowest sacrificial semiconductor layers 106. This results in the shallow trench isolation structures 112 having a top surface that is lower than the bottom surface of the lowest sacrificial semiconductor layer 106 of each fin. Other processes can be utilized to form the shallow trench isolation structures 112 without departing from the scope of the present disclosure. Each trench isolation structure 112 extends in the X direction alongside and between two adjacent semiconductor fins 108.

In some embodiments, the trench isolation structures 112 include SiO2, an oxide formed from tetraethyl orthosilicate, or other suitable dielectric materials. In some embodiments, the trench isolation structures 112 have a depth between 50 nm and 100 nm.

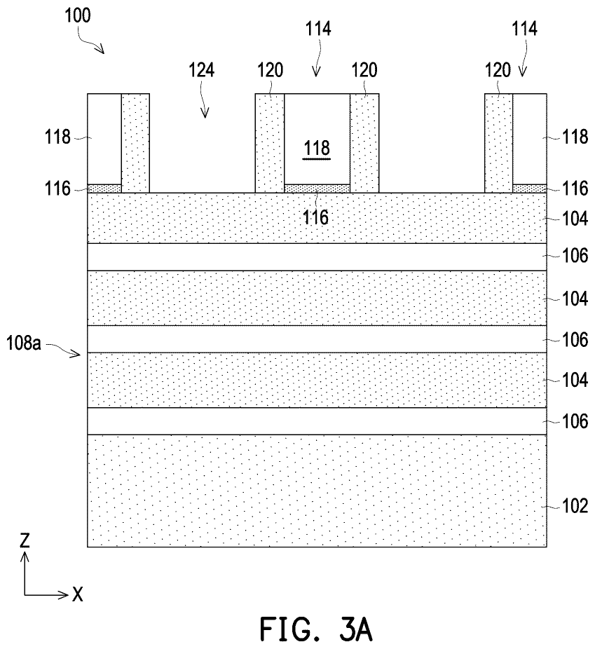

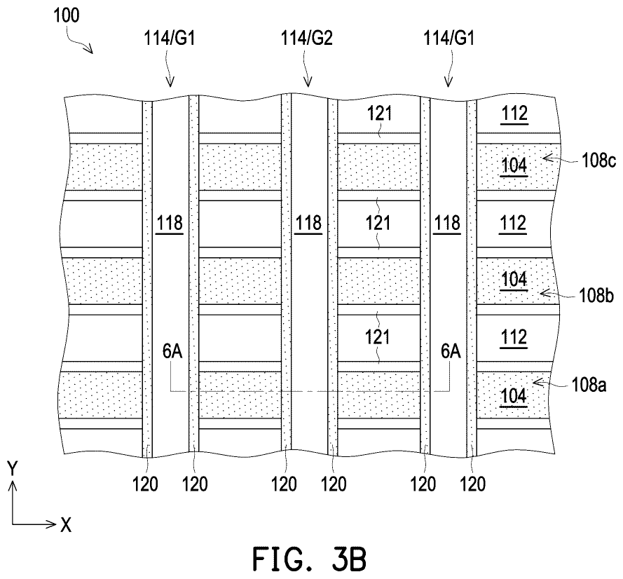

FIG. 3A is a cross-sectional view of the integrated circuit 100, in accordance with some embodiments. FIG. 3B is a top view of the integrated circuit 100 at the stage of processing shown in FIG. 3A. The cross-sectional view of FIG. 3A is taken along cut lines 3A from FIG. 3B.

In FIGS. 3A and 3B, sacrificial gate structures 114 have been formed over the fins 108. Each sacrificial gate structure 114 extends in the Y direction across the semiconductor fins 108 and the trench isolation structures 112. The layout of the sacrificial gate structures 114 corresponds to the layout of gate metals or gate structures of the transistors. In particular, the sacrificial gate structures 114 will eventually be replaced with gate metals. As will be set forth in more detail below, an efficient process will be utilized to cut the gate metals at selected locations between semiconductor fins 108 in order to electrically isolate the gate metals of adjacent transistors, in accordance with a circuit layout of the integrated circuit 100. The sacrificial gate structure 114 corresponds to a respective gate metal layout location G1-G3.

The sacrificial gate structures 114 include a dielectric layer 116. In an exemplary embodiment, the dielectric layer 116 includes silicon oxide. However, alternatively, the dielectric layer 116 can include SiN, SiCN, SiOC, SiOCN, or other dielectric materials without departing from the scope of the present disclosure. In some embodiments, the dielectric layer 116 has a low-K dielectric material. The dielectric layer 116 can be deposited by CVD, ALD, or PVD.

The sacrificial gate structures include a sacrificial gate layer 118 on the dielectric layer 116. The sacrificial gate layer 118 can include materials that have a high etch selectivity with respect to the trench isolation structures 112. In an exemplary embodiment, the sacrificial gate layer 118 includes polysilicon. However, the sacrificial gate layer 118 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 118 may be deposited by physical vapor deposition (PVD), CVD, sputter deposition, or other techniques for depositing the selected material.

In some embodiments, sacrificial gate structures 114 include a dielectric layer on the sacrificial gate layer 118. In an exemplary embodiment, the dielectric layer includes SiN. However, alternatively, the dielectric layer can include SiO, SiCN, SiOC, SiOCN, or other dielectric materials without departing from the scope of the present disclosure. The dielectric layer can be deposited by CVD, ALD, or PVD.

In FIGS. 3A and 3B, gate spacer layers 120 been formed on the sidewalls of the sacrificial gate structures 114. In particular, the gate spacer layer 120 is formed on sidewalls of the dielectric layer 116 and the sacrificial gate layer 118. The gate spacer layer 120 is also formed on top surfaces of the sacrificial gate structures 114, the top semiconductor layer 104 of each semiconductor fin 108, and other exposed surfaces. The gate spacer layer 120 can be formed by PVD, CVD, ALD, or other suitable deposition processes. In a particular example illustrated herein, the gate spacer layer 120 includes SiOCN. Alternatively, the gate spacer layer 120 can include one or more of SiO, SiN, SiON, SiCN, SiOC, or other suitable dielectric materials. In some embodiments, the gate spacer layer 120 has a width between 2 nm and 8 nm, though other thicknesses can be utilized without departing from the scope of the present disclosure.

In FIGS. 3A and 3B, an etching process has been performed to pattern the gate spacer layer 120. The etching process includes an anisotropic etching process that etches in the downward direction. The anisotropic etching process removes the gate spacer layer 120 from horizontal surfaces where the vertical thickness of the gate spacer 120 is small. After patterning of the gate spacer layers, vertically thicker portions of the gate spacer layer 120 remain on sidewalls of the sacrificial gate structures 114.

As can be seen in the top view of FIG. 3B dielectric structures 121 remain on the top surface of the trench isolation structures 112 as remnants of the gate spacer layer 120 after patterning of the gate spacer layer 120. As will be set forth in more detail below, these dielectric structures 121 will restrain the lateral growth of lower portions of source/drain regions.

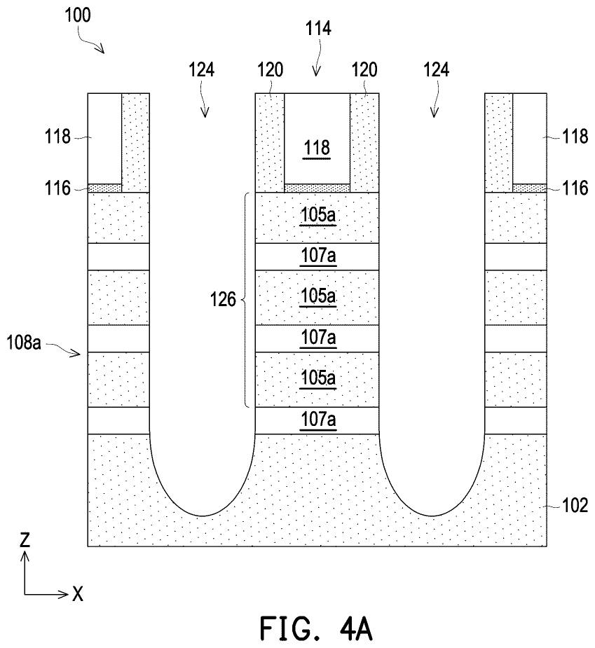

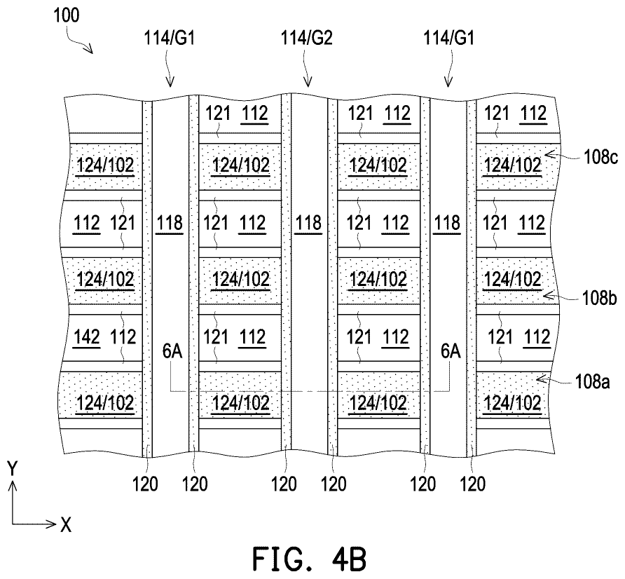

FIG. 4A is a cross-sectional view of the integrated circuit 100, in accordance with some embodiments. FIG. 4B is a top view of the integrated circuit 100 at the stage of processing shown in FIG. 4A. The cross-sectional view of FIG. 4A is taken along cut lines 4A from FIG. 4B.

In FIGS. 4A and 4B, source/drain trenches 124 have been formed, in accordance with some embodiments. After patterning of the gate spacer layer 120, one or more etching processes are performed to form source/drain trenches 124 in the fins 108. Forming the source/drain trenches 124 includes etching through each of the semiconductor layers 104, each of the sacrificial semiconductor layers 106, and a portion of the substrate 102. Accordingly, the removal operations may include suitable etching operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 124 results in formation of stacks 126 of channels 105. In particular, the remaining portions of the semiconductor layers 104 after formation of the source/drain trenches 124 now correspond to stacked channels 105 of a transistor. Formation of the source/drain trenches 124 results in formation of a plurality of sacrificial semiconductor nanostructures 107 from the sacrificial semiconductor layers 106. The substrate 102 is exposed at the bottom of each source/drain trench 124. Each stack 126 of channels 105 corresponds to stacked channels of an individual transistor, as will be set forth in more detail below.

The semiconductor fin 108a includes stacked channels 105a and sacrificial semiconductor nanostructures 107a. The semiconductor fin 108b includes stacked channels 105b (not shown) and sacrificial semiconductor nanostructures 107b (not shown). The semiconductor fin 108c includes stacked channels 105c (not shown) and sacrificial semiconductor nanostructures 107c (not shown).

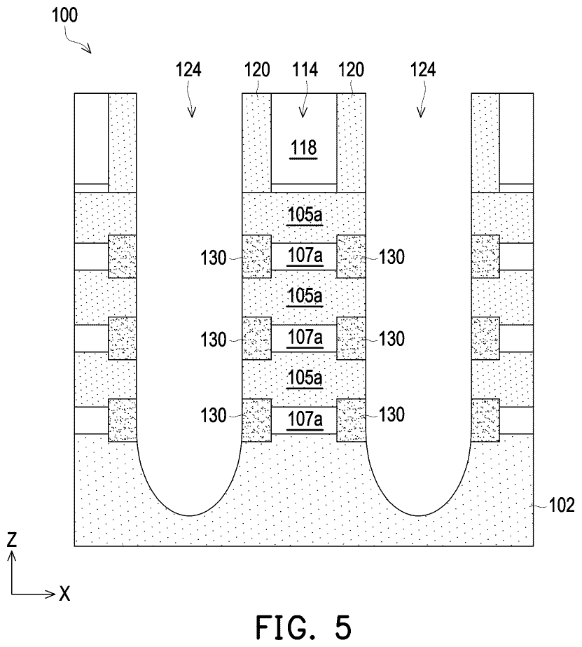

FIG. 5 is a cross-sectional view of the integrated circuit 100, in accordance with some embodiments. In FIG. 5, a selective etching process has been performed to recess exposed end portions of the sacrificial semiconductor nanostructures 107 without substantially etching the channels 105. More particularly, recesses are formed in the end portions of the sacrificial semiconductor nanostructures 107 relative to adjacent channels 105. The recesses can be formed by performing an etching process that selectively etches the material of the sacrificial semiconductor nanostructures 107 with respect to the material of the channels 105 and the substrate 102.

In FIG. 5, inner spacers 130 have been formed in the recesses. The inner spacers 130 are formed by depositing a dielectric layer in a conformal deposition process on exposed surfaces of the channels 105, the gate spacer layer 120, the sacrificial semiconductor nanostructures 107, and the substrate 102. Most notably, the dielectric layer fills the recesses. The dielectric layer can include SiCN, SiOCN, SiON, SiN, or other suitable dielectric materials. The dielectric layer can be formed by a suitable deposition method such as CVD, ALD, PVD, or other deposition processes.

Formation of the inner spacers 130 is completed by performing an anisotropic etching process that etches in the downward direction. During the anisotropic etching process, the gate spacer layer 120 and the sacrificial gate structures 114 function as a mask. The dielectric layer is removed from all locations exposed by the mask. The result is that the dielectric layer is removed from the trenches 124. The portion of the dielectric layer remaining in the recesses corresponds to the inner spacers 130. The inner spacers 130 are in contact with ends of the sacrificial semiconductor nanostructures 107 and with the channels 105. As will be set forth in further detail below, the inner spacers 130 will separate gate metals from source/drain regions.

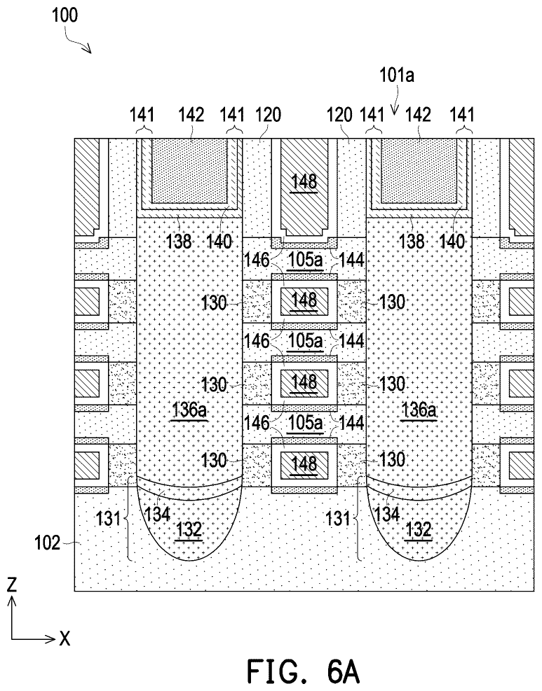

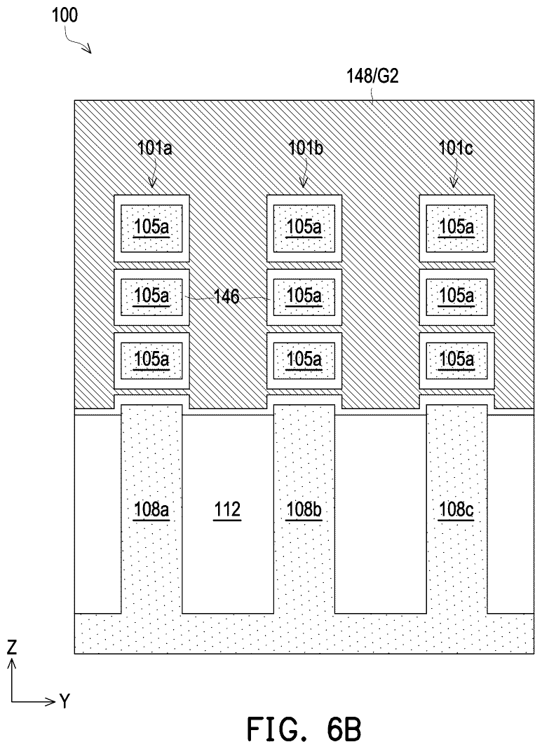

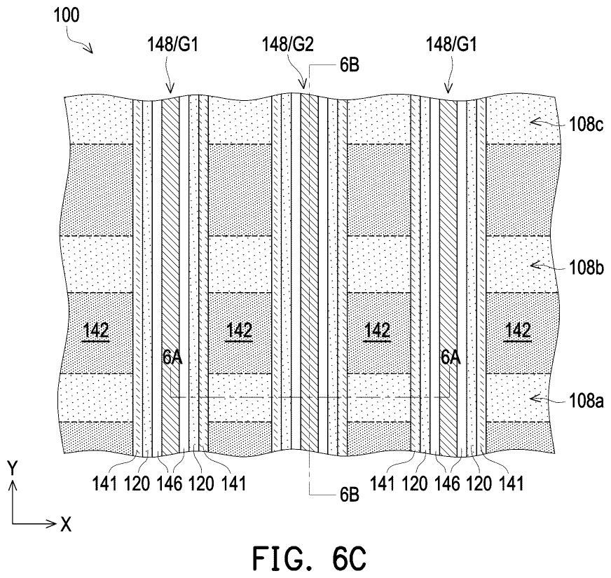

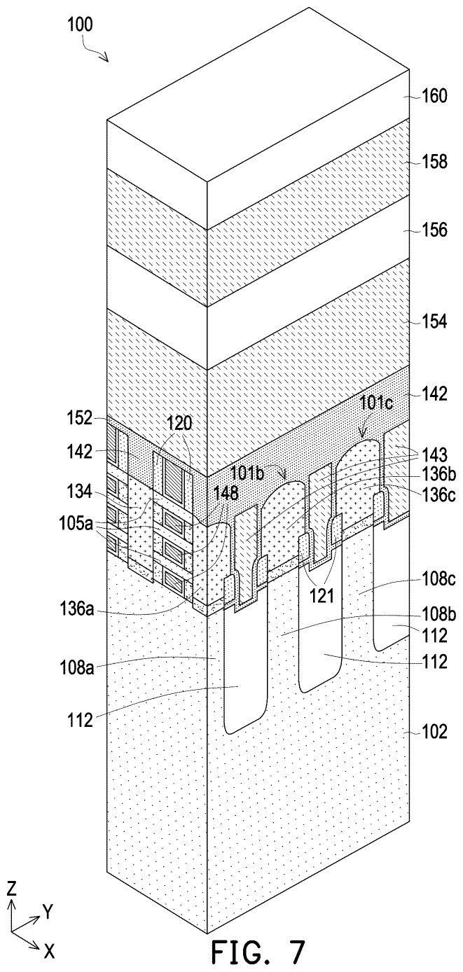

FIGS. 6A and 6B are cross-sectional views of the integrated circuit 100, in accordance with some embodiments. FIG. 6C is a top view of the integrated circuit 100 at the stage of processing shown in FIGS. 6A and 6B. The cross-sectional views of FIGS. 6A and 6B are taken along cut lines 6A and 6B, respectively. The cut line 6A is taken through a portion of the semiconductor fin 108a. The cut line 6B is taken in the Y direction through each of the semiconductor fins 108a-c, and, more particularly, through the gate metal 148 of gate layout G2, as will be set forth in more detail below. The layout of source/drain regions in the Y direction are shown more clearly in the perspective of FIG. 7, described further below.

In FIGS. 6A-6C, bottom semiconductor layers 132 have been formed on the substrate 102 and each source/drain trench 124. In some embodiments, the bottom semiconductor layers 132 include an intrinsic semiconductor material. In some embodiments, the semiconductor material of the semiconductor layers 132 is a same material as the semiconductor material of the substrate 102.

In FIGS. 6A-6C, an interposing layer 131 has been formed at the bottom of each source/drain trench 124. The interposing layer 131 is formed on the semiconductor substrate 102 exposed at the bottom of each source/drain trench 124. In some embodiments, the interposing layer includes an intrinsic (undoped) semiconductor material such as undoped silicon, undoped silicon germanium, or other undoped semiconductor materials. In some embodiments, the interposing layer includes a dielectric material such as SiN, SiCN, SiOCN, SiOC, or other suitable dielectric. In some embodiments, the interposing layer 131 includes a combination of an intrinsic semiconductor layer and a dielectric layer on the intrinsic semiconductor layer.

In the example of FIG. 6A, in accordance with some embodiments, the interposing layer 131 includes a bottom semiconductor layer 132 and a bottom dielectric layer 134 on the bottom semiconductor layer 132. The bottom semiconductor layer 132 includes an intrinsic (undoped) semiconductor material such as undoped silicon, undoped silicon germanium, or other undoped semiconductor materials. The bottom dielectric structures 134 can include SiN, SiCN, SiOCN, SiOC, or other suitable dielectric materials. The bottom dielectric structures 134 can be formed by ALD, CVD, or PVD, followed by selected patterning processes. The bottom dielectric structures 134 can help to prevent leakage currents flowing between source/drain regions 136 and the bottom semiconductor layers 132. In some embodiments, the bottom dielectric structures 134 have a thickness between 2 nm and 8 nm.

In FIGS. 6A-6C, source/drain regions 136 have been formed in the source/drain trenches 124, in accordance with some embodiments. The source/drain regions 136 are epitaxially grown from the channels 105. The source/drain regions 136 are grown on exposed portions of the fins 108 and contact the channels 105. For each stack 126 of channels 105, there are two source/drain regions 136. Some stacks 126 of channels 105 may share a source/drain region 136 with a stack 126 of channels 105 that is adjacent in the X direction.

Source/drain regions 136a are formed in the semiconductor fin 108a. Channels 105a of each stack extend in the X direction between two adjacent source/drain regions 136a, as can be most readily seen in FIG. 6A. Source/drain regions 136b are formed in the semiconductor fin 108b. Channels 105b of each stack extend in the X direction between two adjacent source/drain regions 136b. Source/drain regions 136c are formed in the semiconductor fin 108c. Channels 105c of each stack extend in the X direction between two adjacent source/drain regions 136c. Source/drain regions 136d are formed in the semiconductor fin 108d. Channels 105d of each stack extend in the X direction between two adjacent source/drain regions 136d.

The source/drain regions 136 may include any acceptable semiconductor material, such as appropriate for N-type or P-type devices. For N-type regions, the source/drain regions 136 include materials exerting a tensile strain in the channel regions, such as silicon, SiC, SiCP, SiP, or the like, in some embodiments. For P-type transistors, the source/drain regions 136 include materials exerting a compressive strain in the channel regions, such as SiGe, SiGeB, Ge, GeSn, or the like, in accordance with some embodiments. The source/drain regions 136 may have surfaces raised from respective surfaces of the fins and may have facets. Neighboring source/drain regions 136 may merge in some embodiments to form a singular source/drain region 136 over two neighboring fins 108.

In some embodiments, an in-situ doping process may be performed during formation of the source/drain regions 136 to implant to the source/drain regions 136 with N-type dopants or P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 136 may be implanted with dopants followed by an annealing process. The source/drain regions 136 may have an impurity concentration of between about 10¹⁹ cm⁻³ and about 10²¹ cm⁻³.

Although FIGS. 6A and 6B illustrates each source drain region 136 as a single epitaxial layer, in practice, each source drain region 136 includes a plurality of epitaxial layers, in some embodiments. A first epitaxial layer of the source drain region 136 is grown on ends of the channels 105. A second epitaxial layer of the source/drain region 136 is grown on the first epitaxial layer covers the side surfaces of the inner spacers 130. A final epitaxial layer of the source/drain region 136 is grown on the third epitaxial layer and fills the source/drain trenches 124. Each epitaxial layer of the source/drain region 136 can have different materials and doping profiles.

In FIGS. 6A-6C, dielectric liner layer 138, a contact etch-stop layer (CESL) 140, and an interlevel dielectric (ILD) 142 have been formed, in accordance with some embodiments. In some embodiments, the dielectric liner layer 140 is a thin dielectric layer conformally deposited on exposed surfaces of the source/drain regions 136, on exposed surfaces of the dielectric structures 121, on exposed surfaces of the trench isolation structures 112, on exposed surfaces of the dielectric structures 138, and on exposed surfaces of the gate spacer layers 120. The dielectric liner layer 138 can include SiO, SiN, SiOC, SiOCN, SiON, or other suitable dielectric materials. The dielectric liner layer 138 can be deposited by ALD, CVD, PVD, or other suitable deposition processes. In some embodiments, the dielectric layer 138 is not present.

The CESL 140 can include a thin dielectric layer conformally deposited on the dielectric liner layer 138. The CESL 140 can include SiN, SiC, SiOC, SiOCN, SiON, or other suitable dielectric materials. The CESL 140 can be deposited by CVD, ALD, PVD, or other suitable deposition processes. In a particular example, the dielectric liner layer 138 include silicon oxide and the CESL 140 includes silicon nitride. The dielectric liner layer 138 and the CESL 140 together correspond to a CESL bilayer 141. In some embodiments, CESL bilayer 141 this between 3 nm and 6 nm, though other thicknesses can be utilized without departing from the scope of the present disclosure.

The interlevel dielectric layer 142 covers the CESL 140. The interlevel dielectric layer 142 fills the remaining spaces between adjacent sacrificial gate structures 114. The interlevel dielectric layer 142 may correspond to a lowest interlevel dielectric layer of the integrated circuit 100. In some embodiments, the interlevel dielectric layer 142 may be termed ILD0. Though not shown herein, additional interlevel dielectric layer may be formed over the interlevel dielectric layer 142. A network of conductive vias and metal lines may be formed in the upper interlevel dielectric layers. The interlevel dielectric layer 142 can include SiO, SiON, SiN, SiC, SiOC, SiOCN, SiON, or other suitable dielectric materials. The interlevel dielectric layer 142 can be deposited by CVD, ALD, PVD, or other suitable deposition processes.

In some embodiments, a CMP process is performed after deposition of the interlevel dielectric layer 142. The result of the CMP process is that the top surfaces of the interlevel dielectric layer 142, the CESL 140, the gate spacer layer 120, and the sacrificial gate layer 118 are coplanar. The CMP process may also reduce the height of the sacrificial gate structures 114 and the gate spacer layer 120.

Though not apparent in FIGS. 6A-6C, the source/drain regions 136 extends laterally over the trench isolation structure 112. This is more apparent in the view of FIG. 7.

In FIGS. 6A-6C, the sacrificial gate layer 118 has been removed, in accordance with some embodiments. The sacrificial gate layer 118 can be removed by an etching process that selectively etches the material of the sacrificial gate layer 118 with respect to adjacent materials, such as the dielectric layer 116 and the gate spacer layers 124. Removal of the sacrificial gate layer 118 results in gate trenches between the gate spacer layers 124.

In FIGS. 6A-6C, an etching process has been performed to remove the sacrificial semiconductor nanostructures 107, in accordance with some embodiments. The sacrificial semiconductor nanostructures 107 can be removed by a selective etching process using an etchant that is selective to the material of the channels 105, such that the sacrificial semiconductor nanostructures 107 are removed without substantially etching the channels 105. The removal of the sacrificial semiconductor nanostructures 107 is referred to as “releasing” the channels 105. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 105. The etching process also results in gaps between the channels 105.

In FIGS. 6A-6C, a gate dielectric has been formed, in accordance with some embodiments. The gate dielectric includes an interfacial gate dielectric layer 144 and a high-K gate dielectric layer 146. The interfacial gate dielectric layer 144 has been deposited on exposed portions of the channels 105, in accordance with some embodiments. The interfacial gate dielectric layer 144 forms directly on the exposed portions of the channels 105. The high-K gate dielectric layer 146 forms on the interfacial gate dielectric layer 144 and on other exposed surfaces, such as the exposed sidewalls of the gate spacer layer 120, and the inner spacers 130.

The interfacial gate dielectric layer 144 is wrapped around the channels 105. The interfacial gate dielectric layer 144 can include a dielectric material such as silicon oxide, silicon nitride, or other suitable dielectric materials. The interfacial gate dielectric layer 144 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 144 can be formed by a thermal oxidation process, a chemical vapor deposition (CVD) process, or an atomic layer deposition (ALD) process. The interfacial gate dielectric layer 144 can have a thickness between 0.5 nm and 2 nm. Other materials, deposition processes, and thicknesses can be utilized for the interfacial gate dielectric layer 144 without departing from the scope of the present disclosure. The interfacial gate dielectric layer 144 is shown in FIG. 6A. Though not shown in FIG. 6B, the interfacial gate dielectric layer 144 is also present on the surfaces of the channels 105 between the channels 105 and the high-K gate dielectric layer 146.

The high-K gate dielectric layer 146 is deposited in a conformal deposition process. The conformal deposition process deposits the high-K gate dielectric layer 146 on the interfacial gate dielectric layer 144, on the substrate 102, and on the gate spacer layer 120. The high-K gate dielectric layer 146 is wrapped around the channels 105. The high-K gate dielectric layer 146 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 146 may be formed by CVD, ALD, or any suitable method. Other thicknesses, deposition processes, and materials can be utilized for the high-K gate dielectric layer 146 without departing from the scope of the present disclosure.

In FIGS. 6A-6C, a gate metal 148 has been deposited, in accordance with some embodiments. The gate metal 148 is deposited in place of the sacrificial gate layer 118 and the sacrificial semiconductor nanostructures 107. Accordingly, the gate metal 148 is positioned in the gate trench above the hard mask layer 124 and the above the hard mask layer 150. The gate metal 148 is also wrapped around the channels 105.

As can be seen in FIG. 6B, the gate metal 148 of the gate layout G2 is shorted together around all of the channels 105. Each stack of channels 105a, 105b, and 105c represent an individual transistor 101a, 101b, 101c, respectively. More particularly, each location at which the gate metal 148 crosses a semiconductor fin 108 corresponds to the location of an individual transistor 101. At the stage of processing shown in FIGS. 6A-6C, the gate electrodes of all of the transistors 101a-c of the gate region G2 are shorted together. This is also true for the other gate regions G1 and G3. Though not described herein, a gate metal cut process is utilized to electrically isolate the gate electrodes of adjacent transistors by removing the gate metal at selected locations, in accordance with a circuit layout.

FIG. 6C illustrates that the gate metal 148 of each gate region G1-G3 extends unbroken across the fins 108a-c. The dashed lines in FIG. 6C illustrate the locations of the semiconductor fins 108a-c below the gate regions G1-G3, the gate spacer layers 120, the portions of the high-K gate dielectric layer 146 on the sidewalls of the gate spacer layers 120, the interlevel dielectric layer 142, and the CESL bilayer 141.

In FIGS. 6A-6C, a single gate metal 148 is illustrated as the gate electrode of the transistors 101. However, in practice, the gate metal 148 can include multiple gate metals. For example, the gate metal 148 can include one or more liner layers, one or more work function layers, and a gate fill material that fills the remaining spaces between the gate spacer layers 120. The gate metal 148 can include one or more of Ti, TiN, Ta, TaN, Al, Cu, Co, Ru, W, Au, or other suitable conductive materials. The gate metal 148 can be deposited by PVD, ALD, or CVD.

After formation of the gate metal 148, a CMP process is performed to reduce the height of the gate metal 148 and to make a planar top surface of the remaining structures.

The critical dimension of the semiconductor fins 108 and the Y direction is between 10 nm and 90 nm, in accordance with some embodiments. Other dimensions can be utilized without departing from the scope of the present disclosure.

FIG. 7 is a perspective view of the integrated circuit 100, in accordance with one embodiment. The XZ plane of the perspective view of FIG. 7 cuts along the semiconductor fin 108a. The YZ plane of the perspective view of FIG. 7 cuts through the source/drain regions 136a, 136b, and 136c of the transistors 101a, 101b, and 101c.

The view of FIG. 7 illustrates that an interlevel dielectric layer 143 fills the space between adjacent source/drain regions 136. In some embodiments, the interlevel dielectric layer 143 and the interlevel dielectric layer 142 are a same material deposited in a same process. In some embodiments, the interlevel dielectric layer 143 is a different material deposited in a different deposition process. For example, in some embodiments, the interlevel dielectric layer 143 includes silicon oxide, while the interlevel dielectric layer 142 includes silicon nitride. In some embodiments, the dielectric layers 142 and 143 both include silicon oxide. Other combinations of materials can be utilized without departing from the scope of the present disclosure.

The view of FIG. 7 illustrates that the source/drain regions 136 protrude in the Y direction over the trench isolation structures 112. This is a result of the epitaxial growth process by which the source/drain regions 136 are formed.

In FIG. 7, a dielectric layer 152 has been formed on the top surface of the integrated circuit 100. In particular, the dielectric layer 152 is on the top surface of the gate metal 148, the interlevel dielectric layer 142, and the top surfaces of other exposed structures. In some embodiments, the dielectric layer 152 includes SiN, SiON, SiOCN, SiOC, or other suitable materials. The dielectric layer 152 helps to prevent oxidation of underlying structures, in accordance with some embodiments.

In FIG. 7, a dielectric layer 154 has been formed on the dielectric layer 152. In some embodiments, the dielectric layer 154 includes SiO, SiN, SiON, SiOCN, SiOC, or other suitable materials. Other materials can be utilized without departing from the scope of the present disclosure. The dielectric layer 154 can be deposited by ALD, CVD, PVD, or other suitable deposition processes.

In FIG. 7, a layer 156 has been formed on the dielectric layer 154. In some embodiments, the layer 156 a carbide layer doped with tungsten. In some embodiments, the layer 156 includes SiC, SiOC, or SiOCN with tungsten. Other materials can be utilized without departing from the scope of the present disclosure. The layer 156 can be deposited by ALD, CVD, PVD, or other suitable deposition processes.

In FIG. 7, a dielectric layer 158 has been formed on the layer 156. In some embodiments, the dielectric layer 158 includes SiO, SiN, SiON, SiOCN, SiOC, or other suitable materials. Other materials can be utilized without departing from the scope of the present disclosure. The dielectric layer 158 can be deposited by ALD, CVD, PVD, or other suitable deposition processes. In some embodiments, the dielectric layers 154 and 158 are formed of a same material, such as silicon oxide, or another suitable dielectric material.

In FIG. 7, a layer 160 has been formed on the dielectric layer 158. In some embodiments, the layer 160 amorphous silicon. Other materials can be utilized without departing from the scope of the present disclosure. The layer 160 can be deposited by ALD, CVD, PVD, or other suitable deposition processes.

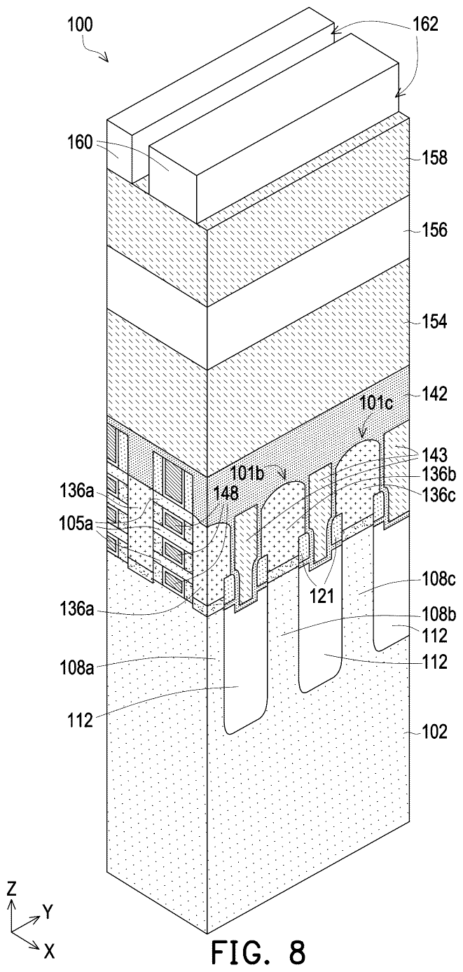

FIG. 8 is a perspective view of the integrated circuit 100, in accordance with some embodiments. In FIG. 8, a photolithography processes been performed to define a pattern for deposition of source/drain contacts in the layer 160. In particular, a plurality of trenches 162 are formed in the layer 160. In FIG. 8, the trenches 162 extends unbroken in the Y direction.

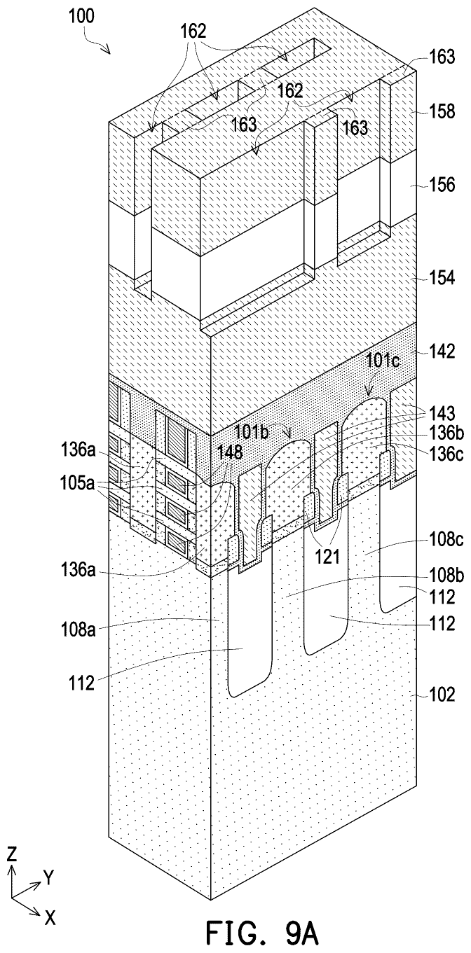

FIG. 9A is a perspective view of the integrated circuit 100, in accordance with some embodiments. In FIG. 9A, a second photolithography process has been performed to define a pattern for source/drain contact cut regions. In particular, the plurality of trenches 162 are carried into the layers 158 and 156 with a pattern that has been altered with respect to the pattern shown in FIG. 8. In particular, the trenches 162 are divided by regions 163 of the dielectric layer 158. The regions 163 correspond to a pattern of source/drain cut regions. Together, the photolithography processes of FIGS. 8 and 9A will define the actual layout of a first layer of source/drain contact metal, as will be set forth in more detail below.

In FIG. 9A, the layer 160 has been removed after patterning the layer 158. The layer 158 now functions as a hard mask.

FIG. 9B is a representation of a layout 900 of the integrated circuit 100 at the stage of processing shown in FIG. 9A. The layout 900 is not a view of the integrated circuit 100 or of any structure of the integrated circuit 100. The layout 900 illustrates active regions A1, A2, and A3 corresponding to the positions of the semiconductor fins 108a-c. The width of the active regions A1-A3 represents in the Y direction corresponds to the width of the source/drain regions 136 in the Y direction. As has been established previously, the source/drain regions 136 overhang the trench isolation structures 112 and are, thus, somewhat wider in the Y direction than the semiconductor fins 108 in which they are grown.

The layout 900 illustrates gate regions G1-G3, corresponding to the positions of the gate metal 148, as described previously. The layout 900 illustrates source/drain contact lines SDC1 and SDC2. The source/drain contact lines SDC1 and SDC2 represents the positions of the trenches 162 at the stage of processing shown in FIG. 8. The layout 900 illustrates source/drain contact cut lines SDCC1 and SDCC2. The source/drain contact cut lines represent areas at which source/drain contact metals will not be present. Accordingly, the regions 163 of FIG. 9A correspond to locations at which the source/drain contact lines SDC cross the source/drain contact cut lines SDCC. As can be seen in FIG. 9B, SDCC2 has two different widths in the Y direction. As will be set forth in more detail below, the smaller width correspond to a location adjacent to which a source/drain contact including two stacked metals will be formed.

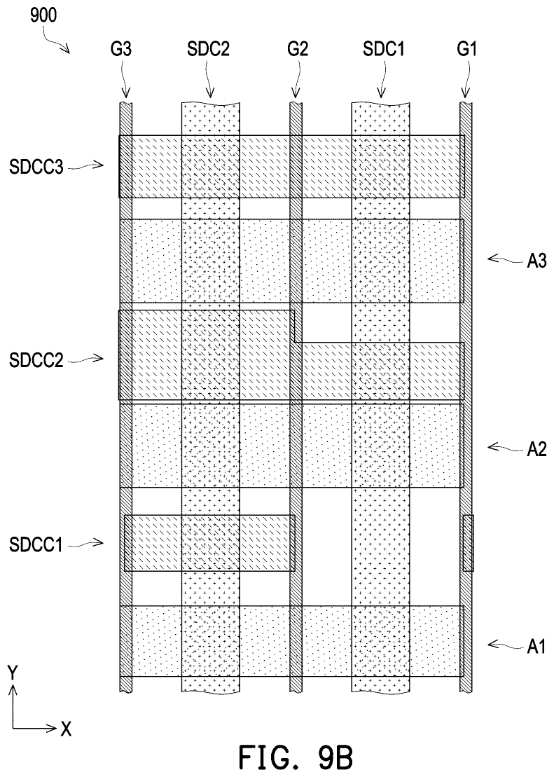

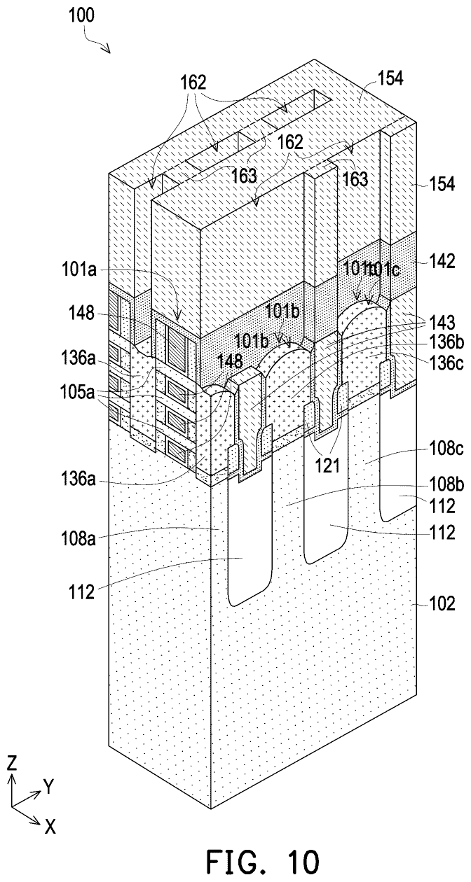

FIG. 10 is a perspective view of the integrated circuit 100, in accordance with some embodiments. In FIG. 10, one or more etching processes have been performed to extend the recesses 162 further into the integrated circuit 100. In particular, the one or more etching processes etch through the dielectric layers 154, 152, and 142 to expose the top surfaces of the source/drain regions 136. The one or more etching processes also expose the dielectric layer 143. Those portions of 142 that are removed correspond to the places at which metal will be deposited for the source/drain contacts. The etching processes can include anisotropic etching processes that etch selectively in the downward direction. The anisotropic etching processes can include reactive ion etching or other types of etching. The one or more etching processes may recess the top surface of the source/drain regions 136.

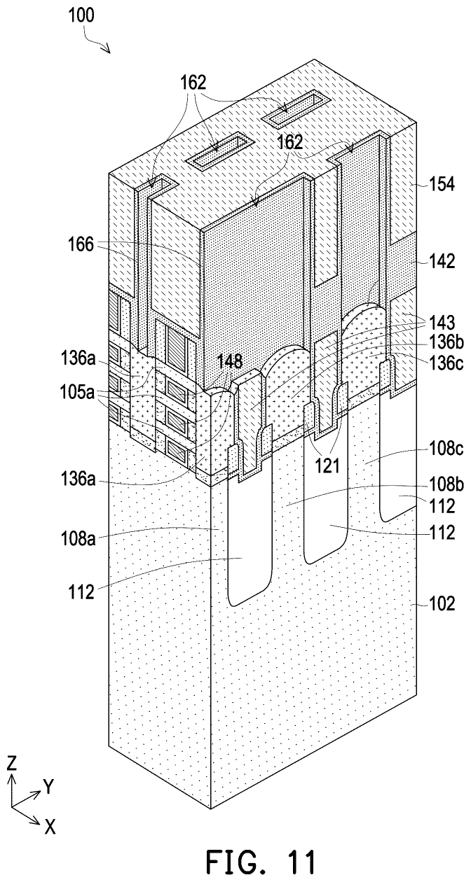

FIG. 11 is a perspective view of the integrated circuit 100, in accordance with some embodiments. In FIG. 11, a dielectric liner layer 166 has been deposited on sidewalls of the trenches 162. The dielectric liner layer 166 lines exposed side surfaces of the dielectric layers 142 and 154. The dielectric liner layer 166 can include SiN, SiON, SiOCN, SiCN, or other suitable dielectric materials. The dielectric liner layer 166 can be deposited by ALD, CVD, PVD, or other suitable deposition processes. In some embodiments, after deposition of the dielectric liner layer 166, the dielectric layer 166 is etched to exposed source/drain regions 136.

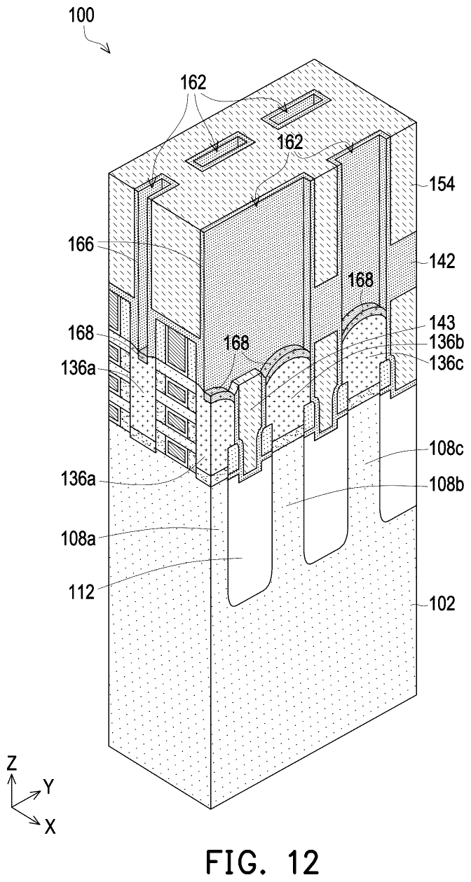

FIG. 12 is a perspective view of the integrated circuit 100, in accordance with some embodiments. In FIG. 12, a silicide layer 168 has been formed in preparation for forming source/drain contacts. Formation of the silicide layer 168 can include depositing a thin metal layer Ti, Ni, Al, Ta, or other suitable metal and performing a thermal annealing process that results in formation of the silicide layer 168 from the metal layer. Accordingly, the silicide layer 168 can include titanium silicide, nickel silicide, aluminum silicide, tantalum silicide, or other suitable silicides.

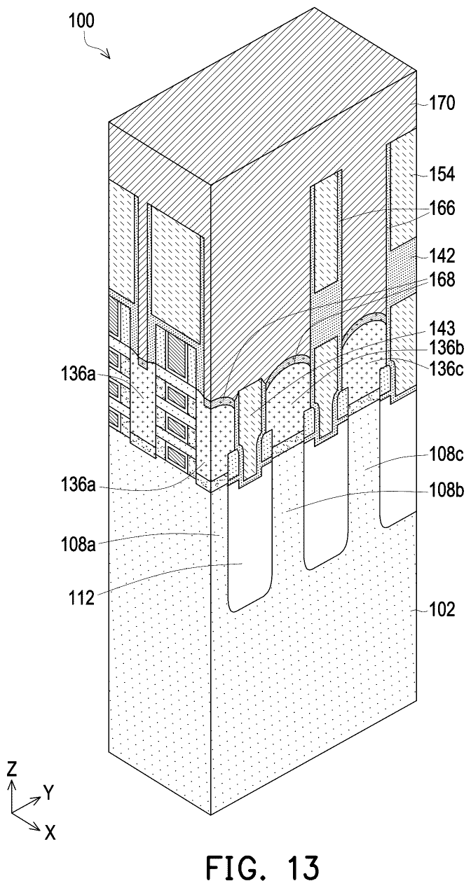

FIG. 13 is a perspective view of the integrated circuit 100, in accordance with some embodiments. In FIG. 13, a metal layer 170 has been deposited. The metal layer 170 fills the trenches 162. As will be set forth in more detail below, the metal layer 170 is utilized to form source/drain contacts. In some embodiments, the metal layer 170 includes tungsten. Alternatively, the metal layer 170 can include Ta, Ti, Al, Ru, Co, Au, or other suitable materials. In some embodiments, a liner layer of titanium nitride or tantalum nitride is formed on the silicide and on the dielectric liner layer 166 prior to forming the metal layer 170. In some embodiments, the metal layer 170 is formed directly on the silicide 168. The metal layer 170 can be deposited by PVD, ALD, CVD, or other suitable deposition processes. In some embodiments, the metal layer 170 can be formed in a bottom-up approach. In some embodiments, the metal layer 170 includes tungsten formed in a bottom-up approach. In some embodiments, a liner layer of TiN is deposited prior to depositing the metal layer 170.

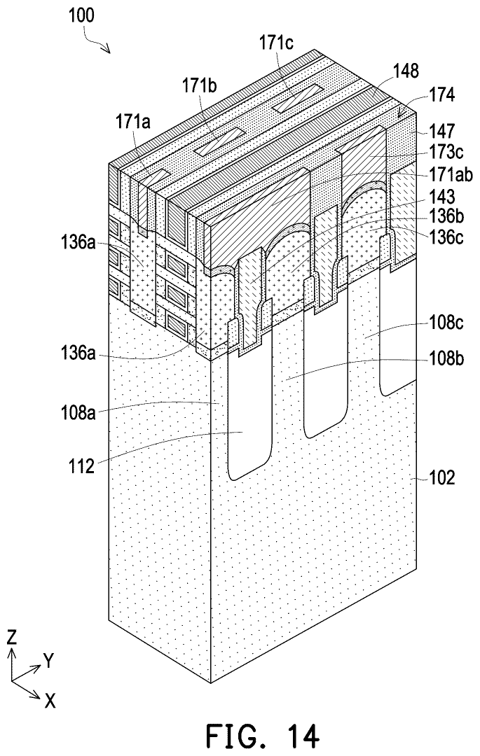

FIG. 14 is a perspective view of the integrated circuit 100, in accordance with some embodiments. In FIG. 14, a CMP process has been performed, in accordance with some embodiments. The CMP process removes the dielectric layer 154, removes the dielectric layer 152, and reduces the height of the metal layer 170. The reduction in the height of the metal layer 170 results in the formation of individuals source/drain contacts 171a, 171b, 171c of the transistors 101a-c, a joint source/drain contact 171ab of the transistors 101a and 101b, and a first portion 173c of a source/drain contact 171c. The CMP process has the effect of electrically isolating source/drain contacts 171 from each other in accordance with the pattern of the source/drain contact cut lines SDCC. As will be set forth in more detail below, one of the source/drain contacts 171c will include a second portion formed on a top surface of the first portion 173c.

In some embodiments, the top surface of the gate metal 148 is coplanar with the top surfaces of the source/drain contacts 171. In some embodiments, the gate metal 148 acts as an etch stop for the CMP process.

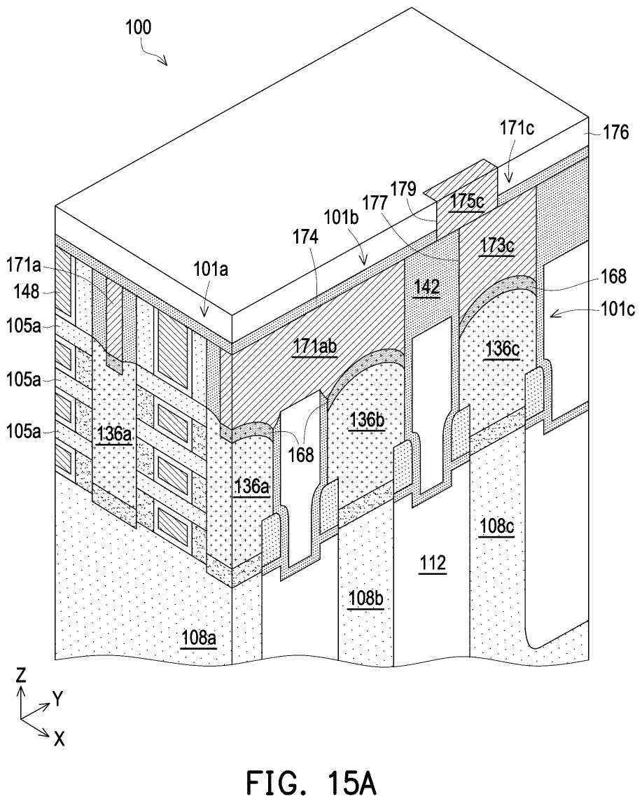

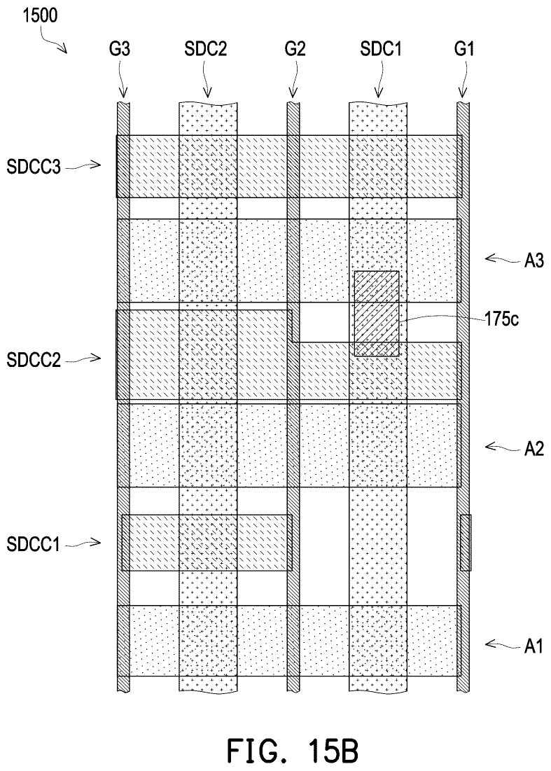

FIG. 15A is a perspective view of the integrated circuit 100, in accordance with some embodiments. In FIG. 15A, a dielectric layer 174 has been deposited on the top surface of the source/drain contacts 171, the first portion 173c, the gate metal 148, and other exposed surfaces. The dielectric layer 174 functions as an etch stop layer, in some embodiments. The dielectric layer 174 includes one or more of SiN, SiCN, SiOCN, SiOC, or other suitable dielectric materials. The dielectric layer 174 is deposited by CVD, ALD, PVD, or other suitable deposition processes.

In FIG. 15A, a dielectric layer 176 has been deposited on the dielectric layer 174, in accordance with some embodiments. The dielectric layer 176 is an interlevel dielectric layer including SiO, SiN, or other suitable dielectric materials. The dielectric layer 176 is deposited by CVD, ALD, PVD, or other suitable deposition processes.

In FIG. 15A a photolithography process has been performed to form an opening in the dielectric layers 176 and 174 to expose a portion of the top surface of the first portion 173c of the source/drain contact 171c, and a portion of the dielectric layer 142 over the trench isolation region 112 between the semiconductor fins 108b and 108c.

In FIG. 15A, a metal layer has been deposited in the opening in the dielectric layers 176 and 174. A CMP process has been performed to remove excess metal material from the top surface of the dielectric layer 176. This results in formation of the second portion 175c of the source/drain contact 171c on the top surface of the first portion 173c of the source/drain contact 171c. Accordingly, the source/drain contact 171c visible in FIG. 15A includes the first portion 173c and the second portion 175c. The first portion 173c may be termed a first source/drain metal of the source/drain contact 171c. The second portion 175c may be termed a second source/drain metal of the source/drain contact 171c.

The first portion 173c has a lateral edge or side surface 177 adjacent to the source/drain contact 171ab. The second portion 175c has a lateral edge or side surface 179 that is positioned further in the Y direction toward the source/drain contact 171ab. Accordingly, the second portion 175c overlaps the side surface 177 of the first portion 173c. The second portion 175c extends further over the trench isolation structure 112 than does the first portion 173c. The first portion 173c has a total width in the Y direction that is greater than a total width of the second portion 175c in the Y direction. Further details regarding the dimensions is provided below.

FIG. 15B is a layout 1500 associated with the integrated circuit 100 at the stage of processing shown in FIG. 15A, in accordance with some embodiments. The layout 1500 is substantially similar to the layout 900 of FIG. 9B, except that the layout 1500 illustrates the position of the second portion 175c. The second portion 175c overlaps both the active region A3 (and the semiconductor fin 108c) and the trench isolation structure 112.

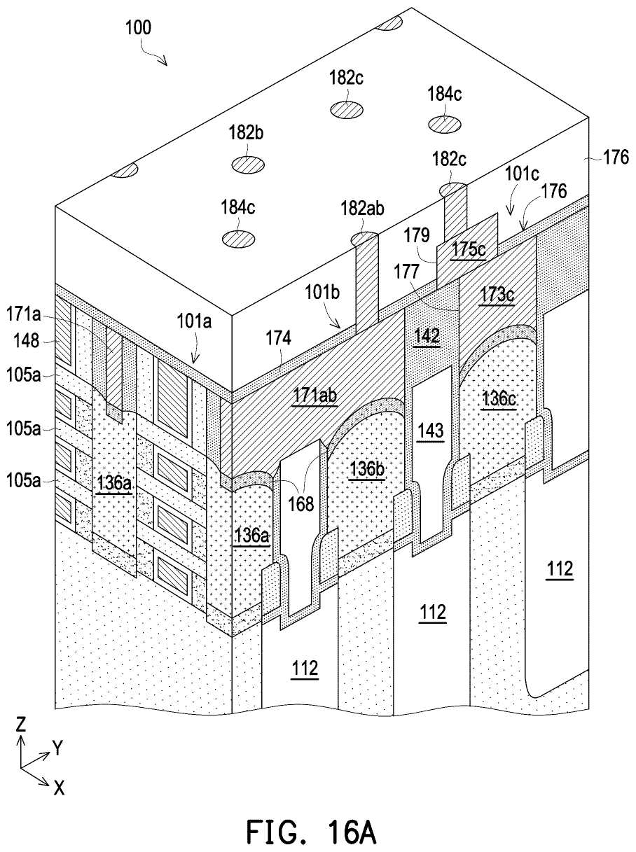

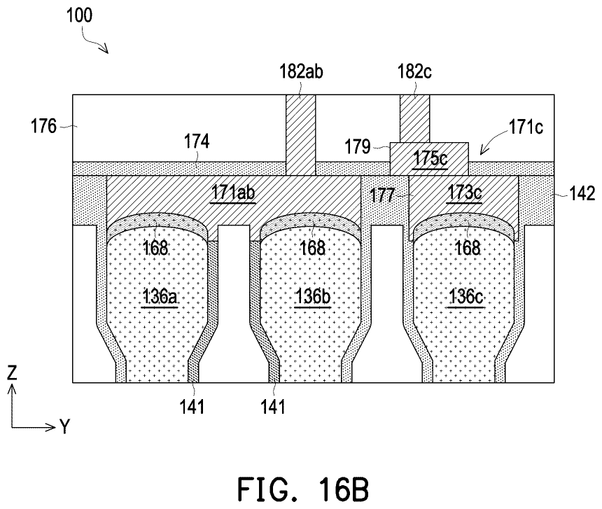

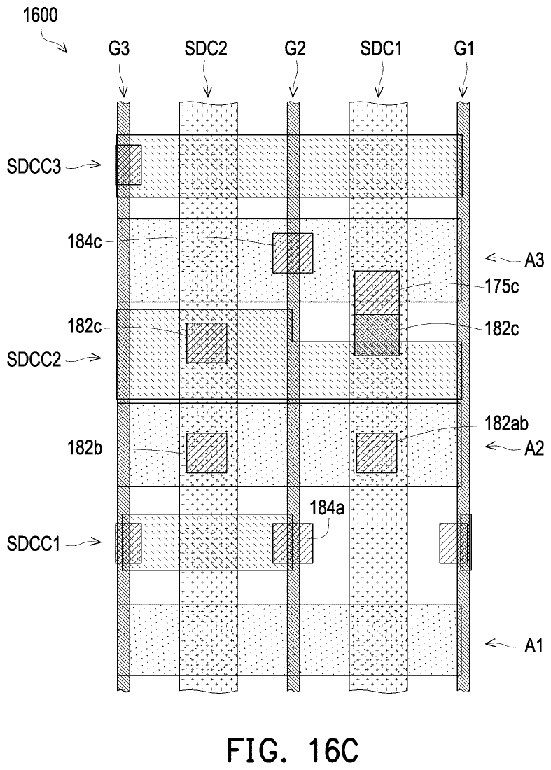

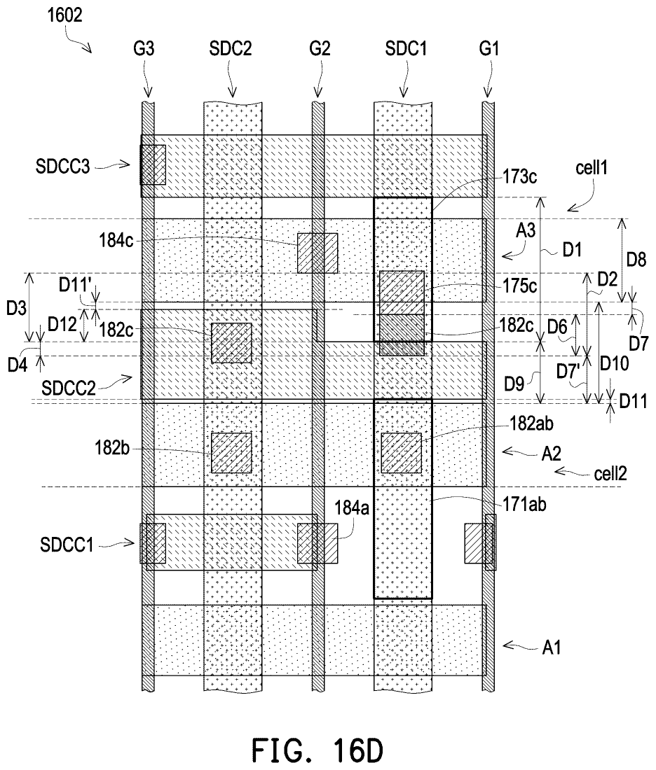

FIG. 16A is a perspective view of the integrated circuit 100, in accordance with some embodiments. In FIG. 16A, the interlevel dielectric layer 176 has been regrown. This could also be considered as growing a second sub layer of the interlevel dielectric layer 176 on the top surface of a of the interlevel dielectric layer 176. The second sublayer can have a same material as the first sublayer.

In FIG. 16A, source/drain conductive vias 182 and gate conductive vias 184 have been formed in the interlevel dielectric layer 176. The source/drain conductive vias 182 are in contact with a top surface of a source/drain contact 171. The gate conductive vias 184 are in contact with a top surface of the gate metal 148. The conductive vias 182/184 are formed with a photolithography and corresponding etching process that forms apertures in the interlevel dielectric layer 176. A deposition process is then performed to deposit the metal of the conductive vias 182/184 in the openings. The metal of the conductive vias can include W, Ta, Ti, Co, Au, Ru, Al, or other suitable conductive materials. The metal can be deposited via PVD, ALD, CVD, or other suitable deposition processes.

A source/drain conductive via 182ab contacts a top surface of the source/drain contact 171ab. A source/drain conductive via 182c contacts a top surface of the second portion 175c of the source/drain contact 171c. A source/drain conductive via 182b contacts a top surface of the source/drain contact 171b. A gate conductive via 184a contacts a portion of the gate metal 148 corresponding to a gate electrode of the transistor 101a. A gate conductive via 184c contacts a portion of the gate metal 148 corresponding to a gate electrode of the transistor 101c.

In some embodiments, the conductive via 182c overlaps the edge 177 of the first portion 173c of the source/drain contact 171c. The conductive via 182c also overlaps the trench isolation structure 112.

FIG. 16B is a cross-sectional view of the integrated circuit 100 at the stage of processing of FIG. 16A, in accordance with some embodiments. The cross-sectional view of FIG. 16B corresponds to the YZ face of the perspective view of FIG. 16A. One advantage of the process for forming the source/drain contacts 171 including the stack of source/drain contact metals (e.g., in the source/drain contact 171c) is that the silicide 168 of each of the source/drain regions 136 completely covers the top surface of the source/drain regions 136. Accordingly, there is no exposed source/drain material adjacent to the source/drain contacts 171. This enables formation of source/drain regions are closer to neighboring source/drain contacts. As a result, the reliability (time-dependent dielectric breakdown) is improved. Leakage currents and short circuits are reduced. Furthermore, as will be set forth in more detail below, the second portion 175c of a source/drain contact can function as a power rails supplying VDD or VSS (ground). In some embodiments, the source/drain contact 171c covers sidewalls of the silicide.

FIG. 16C is a layout 1600 associated with the stage of processing of the integrated circuit 100 shown in FIGS. 16A and 16B, in accordance with some embodiments. The layout 1600 is substantially similar to the layout 1500, except that the positions of the conductive vias 182/184 are illustrated.

FIG. 16D is a layout 1602 associated with the stage of processing of the integrated circuit 100 shown in FIGS. 16A and 16B, in accordance with some embodiments. The layout 1602 is substantially similar to the layout 1600, except that boundaries of source/drain contacts 171ab and 171c are outlined and dimensions D1-D12 are illustrated.

In some embodiments, D1 is between 8 nm and 100 nm. In some embodiments, D2 is between 8 nm and 100 nm. In some embodiments, D1/D2 ratio is between 1 and 13. In some embodiments, the overlap D3 between 175c and 173c is between 13 nm and 20 nm. In some embodiments, 175c extends beyond 173c (D4) between 6 nm and 13 nm. In some embodiments, the D3/D4 ratio is between 1 and 4. In some embodiments, D4 may be greater than D3. In some embodiments, the source/drain contact has a width D6 in the Y dimension between 8 nm and 12 nm. In some embodiments, the distance D7 between 182c and the active region A3 is less than the distance D7′ between 182c and A2. In some embodiments, the active regions A1-A3 have a width D8 between 10 nm and 60 nm. In some embodiments, the narrow portion D9 of the SDCC2 is between 10 nm and 15 nm. In some embodiments, the distance D10 between active regions is between 15 nm and 28 nm. In some embodiments, the distance D11 between SDCC 2 and A1 is between 0.5 nm and 6 nm. In some embodiments, the distance D11′ is between 0.5 nm and 6 nm. In some embodiments D11 is the same as D11′. In some embodiments, D11 and D11′ are different. In some embodiments, the dimension D12 is between 0 nm and 8 nm. In some embodiments, the D11/D10 ratio is between 0.02 and 0.4. In some embodiments, the D9/D10 ratio is between 0.3 and 1. In some embodiments, D11 is less than D9. In some embodiments, D9 is less than D11. In some embodiments, D11 is less than D6. In some embodiments, D6 is less than D11. In some embodiments, D11 is less than D7′. In some embodiments, D7′ is less than D11. In some embodiments, the width of 175c in the X direction is less than or equal to 173c.

The integrated circuit 100 and corresponding layout of FIGS. 16A-16D, as well as the process shown and described in relation to FIGS. 1-16C provides several benefits. Each active region corresponds to a logic cell. The cell boundary is positioned over the SDCC between the active regions. In some embodiments, layout rules for the first metal layer are not able to move toward the inside of the logic cell corresponding to A3 as it could reduce the critical dimension of the metal lines. This calls for the conductive via 182c to be disposed near the cell boundary (halfway between A3 and A2. Beneficially, the utilization of the stack of source/drain contact metals enables the conductive via 182c to be placed near the cell boundary.

In some embodiments, the source/drain conductive via 182ab is not connected to a VDD/VSS power rail directly above the active region A2. The source/drain contact 171ab entirely covers the silicide 168 and the source/drain regions 136a/b, thereby improving time-dependent dielectric breakdown.

In some embodiments, SDCC move toward the cell boundary and keep the same dimension, thereby avoiding shrinkage that could result in a short between adjacent source/drain contacts. Another SDCC moves toward the cell boundary and keeps the same dimension.

In some embodiments, although the second portion 175c of the source/drain contact 171c is close to the source/drain contact 171ab, the distance between them can be well-controlled by the photolithography process that implements the pattern of the second portion 175c of the source/drain contact 171c. This is in contrast to the difficulty of decreasing distances between 173c and 171ab as it is more difficult to control the lateral growth of the source/drain regions.

In some embodiments, the top surface of the first portion 173c and the other source/drain contacts 171 is at a same height or is coplanar with the top surface of the gate metal 148. In some embodiments, the top surface of the second portion 175c is between 6 nm and 10 nm higher than the top surface of the gate metal 148. In some embodiments, a recess of the second source/drain contact metal below the top surface of the gate metal 148 can occur due to the etching process. In some embodiments, the reset depth is between 0 nm and 10 nm.

In some embodiments, the source/drain contacts 171 (and first portion 173c) have a width in the X direction between 9 nm and 20 nm and a width in the Y direction between 8 nm and 100 nm. in some embodiments, the width of the second portion 175c in the X direction is between 6 nm and 10 nm and between 8 nm and 100 nm in the Y direction. In some embodiments, the ratio of the width of the first portion 175c in the Y direction to the width of the second portion 175c in the Y direction is between 1 and 13. In some embodiments, 175c and 173c overlap each other in the Y direction between 13 nm and 20 nm. In some embodiments, 175c extends beyond the edge 177 of 173c between 6 nm and 13 nm. Other dimensions can be utilized without departing from the scope of the present disclosure.

In some embodiments, the conductive vias 182 that land on the second portions 175 of source/drain contacts 171 can be a power rail type. In some embodiments, source/drain conductive vias can have different heights. For example, the source/drain conductive via 182ab can have a height between 12 nm and 30 nm, while the source/drain contact 182c can have a height between 6 nm and 18 nm. In some embodiments, the second portion 175c overlaps the edge 177 of the first portion 173c by between 2 nm and 3 nm. In some embodiments, the ratio of the height of 175c to the height of 173c is between 0.2 and 0.8. Other dimensions can be utilized without departing from the scope of the present disclosure.

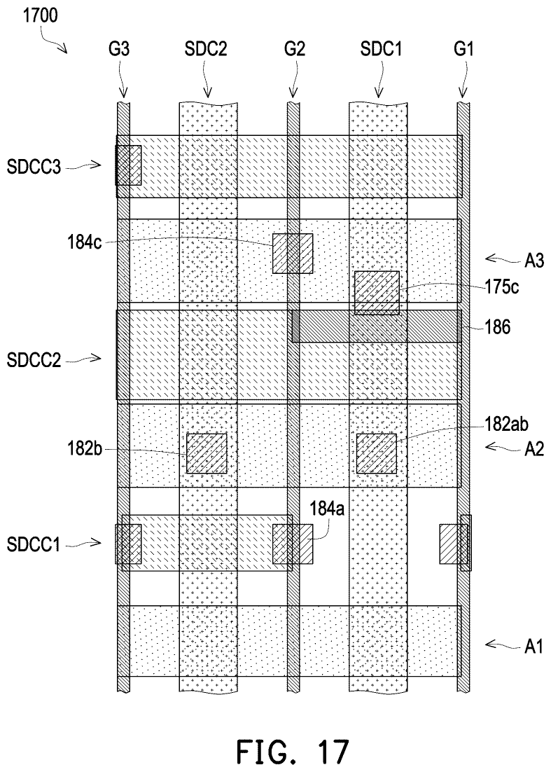

FIG. 17 is a layout 1700 associated with an integrated circuit 100, in accordance with some embodiments. The layout 1700 is substantially similar to the layout 1600 of FIG. 16C, except that the position of the conductive via 182c is replaced with a power rail 186 that supplies either VDD or VSS (ground). The width in the X direction of the power rail 186 is approximately equal to the distance in the X direction between G1 and G2, or between 20 nm and 100 nm.

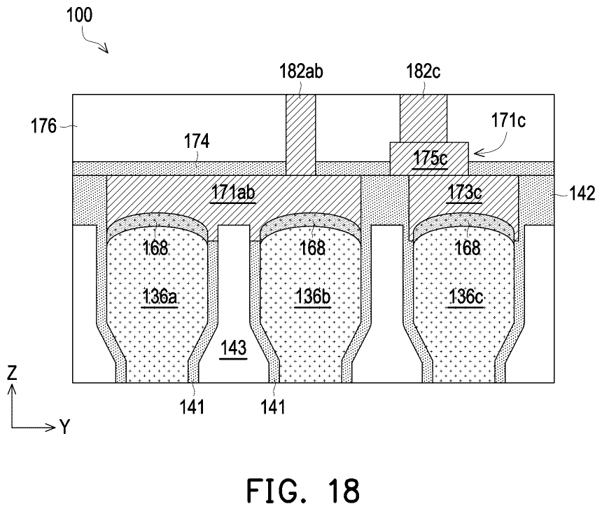

FIG. 18 is a cross-sectional view of an integrated circuit 100, in accordance with some embodiments. The integrated circuit 100 of FIG. 18 is substantially similar to the integrated circuit 100 of FIG. 16B, except that the source/drain conductive via 182c is wider and shorter than the source/drain conductive via 182ab. In some embodiments, this provides a reduced electrical resistance in the source/drain conductive via 182c.

FIG. 19 is a layout 1900 associated with an integrated circuit 100, in accordance with some embodiments. The layout 1900 is substantially similar to the layout 1600 of FIG. 16C, except that the SDCC2 has a uniform width in the Y direction. Furthermore, D4 is greater than or equal to D3.

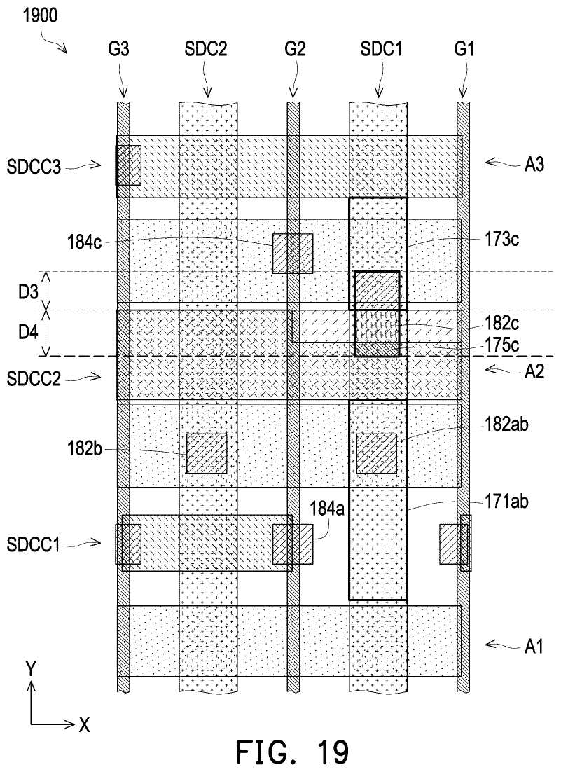

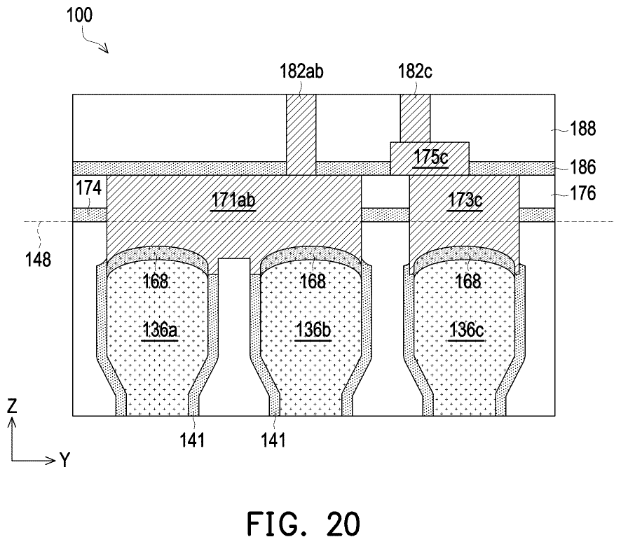

FIG. 20 is a cross-sectional view of an integrated circuit 100, in accordance with some embodiments. The integrated circuit 100 of FIG. 20 is substantially similar to the integrated circuit 100 of FIG. 16B, except that the source/drain contacts 171 (and the first portion 173) have a top surface than a top surface of the gate metal 148. The level of the top surface of the gate metal 148 is represented with the dashed line. In some embodiments, the top surface of 171ab is between 5 nm and 20 nm higher than the top surface of the gate metal 148, though other dimensions can be utilized without departing from the scope of the present disclosure.

The integrated circuit 100 further includes a dielectric layer 186 and a dielectric layer 188. The dielectric layer 188 is an interlevel dielectric layer can include SiO, SiN, or other suitable dielectric materials. The dielectric layer 186 is an etch stop layer and includes SiN, SiCN, SiOCN, SiOC, or other suitable dielectric materials.

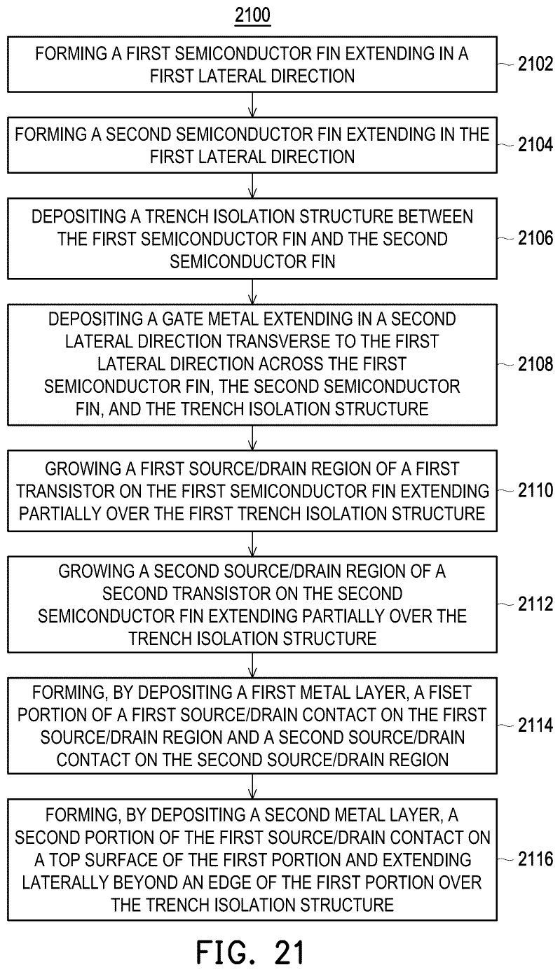

FIG. 21 is a flow diagram of a method 2100 for forming an integrated circuit, in accordance with some embodiments. The method 2100 can utilize the structures, processes, and systems described in relation to FIGS. 1-20. At 2102, the method 2100 includes forming a first semiconductor fin extending in a first lateral direction. One example of a first semiconductor fin is the semiconductor fin 108c of FIG. 2A. At 2104, the method 2100 includes forming a second semiconductor fin extending in the first lateral direction. One example of a second semiconductor fin is the semiconductor fin 108b of FIG. 2A. At 2106, the method 2100 includes depositing a trench isolation structure between the first semiconductor fin and the second semiconductor fin. One example of a trench isolation structure is the trench isolation structure 112 of FIG. 2B. At 2108, the method 2100 includes depositing a gate metal extending in a second lateral direction transverse to the first lateral direction across the first semiconductor fin, the second semiconductor fin, and the trench isolation structure. One example of a gate metal is the gate metal 148/G2 of FIG. 6C. At 2110, the method 2100 includes growing a first source/drain region of a first transistor on the first semiconductor fin extending partially over the first trench isolation structure. One example of a first transistor is the transistor 101c of FIG. 7. One example of a first source/drain region is the source/drain region 136c of FIG. 7. At 2112, the method 2100 includes growing a second source/drain region of a second transistor on the second semiconductor fin extending partially over the trench isolation structure. One example of a second transistor is the transistor 101b of FIG. 7. One example of a second source/drain region is the source/drain region 136b. At 2114, the method 2100 includes forming, by depositing a first metal layer, a first portion of a first source/drain contact on the first source/drain region and a second source/drain contact on the second source/drain region. One example of a first source/drain metal layer is the metal layer 170 of FIG. 13. One example of a first portion of a first source/drain contact is the first portion 173c of FIG. 14. One example of a second source/drain contact is the source/drain contact 171ab of FIG. 14. At 2116, the method 2100 includes forming, by depositing a second metal layer, a second portion of the first source/drain contact on a top surface of the first portion and extending laterally beyond an edge of the first portion over the trench isolation structure. One example of a second portion of a first source/drain contact is the second portion 175c of the source/drain contact 171c of FIG. 15.

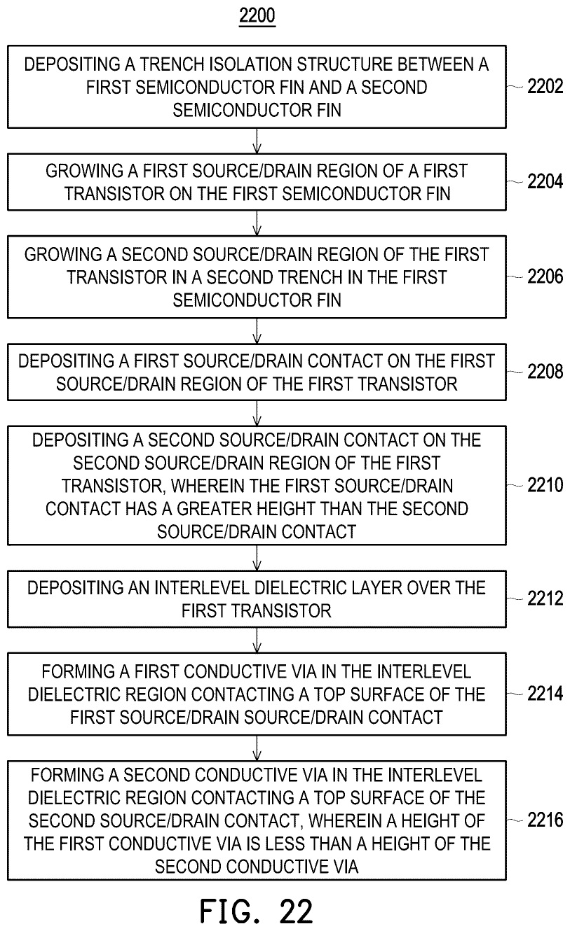

FIG. 22 is a flow diagram of a method 2200 for forming an integrated circuit, in accordance with some embodiments. The method 2200 can utilize the structures, processes, and systems described in relation to FIGS. 1-20. At 2202, the method 2200 includes depositing a trench isolation structure between a first semiconductor fin and a second semiconductor fin. One example of a trench isolation structure is the trench isolation structure 112 of FIG. 2B. One example of a first semiconductor fin is the semiconductor fin 108b of FIG. 2B. One example of a second semiconductor fin is the semiconductor fin 108b of FIG. 2B. At 2204, the method 2200 includes growing a first source/drain region of a first transistor in a first trench in the first semiconductor fin. One example of a first transistor is the transistor 101c of FIG. 7. At 2206, the method 2200 includes growing a second source/drain region of a first transistor in a second trench in the first semiconductor fin. One example of first and second source/drain regions are the source/drain regions 136c of FIG. 7. At 2208, the method 2200 includes forming a first source/drain contact on the first source/drain region of the first transistor. At 2210, the method 2200 includes forming a second source/drain contact on the second source/drain region of the first transistor, wherein the first source/drain contact has a greater height that the second source/drain contact. One example of a second source/drain contact is the source/drain contact 171c of FIG. 15. At 2212, the method 2200 includes forming an interlevel dielectric layer over the first transistor. One example of an interlevel dielectric layer is the interlevel dielectric layer 176 of FIG. 16A. At 2214, the method 2200 includes forming a first conductive via in the interlevel dielectric region contacting a top surface of the first source/drain source/drain contact. At 2216, the method 2200 includes forming a second conductive via in the interlevel dielectric region contacting a top surface of the second source/drain contact, wherein a height of the first conductive via is less than a height of the second conductive via. One example of first and second conductive vias are the conductive vias 136c of FIG. 16C.

In accordance with some embodiments, active regions are implemented in conjunction with semiconductor fins that extend in a first lateral direction (e.g., X direction). Trench isolation structures extend in the first lateral direction alongside and between adjacent semiconductor fins. Gate regions extend across the semiconductor fins and the trench isolation structures in a second lateral direction (e.g., Y direction). Source/drain regions of transistors are formed in the semiconductor fins, with stacked channels being positioned in the semiconductor fins where the gate regions cross the semiconductor fins. At a layout level, source/drain contact metals extend in the second lateral direction. Source/drain contact cut regions extend in the first lateral direction above the trench isolation structures. Where a source/drain contact cut region crosses a source/drain contact region, the source/drain contact metals are removed or are not formed so that source/drain contacts of adjacent transistors can be electrically isolated from each other.

Embodiments of the present disclosure provide source/drain contacts that enable continued scaling of active region pitches and trench isolation structure dimensions. In some embodiments, the source/drain contact cut regions do not overlap the semiconductor fins but are instead located entirely over the trench isolation structures. Embodiments of the present disclosure enable selected source/drain contacts to be formed using a stack of two source/drain contact metals. More particularly, when adjacent source/drain regions of two transistors formed in different semiconductor fins are to be electrically isolated from each other and both are to be contacted by respective conductive vias, one of the source/drain contacts includes the stack of two metals, while the other includes only one source/drain contact metal. In the stack of two source/drain contact metals, the higher metal overlaps an edge of the lower metal such that the higher metal is closer to the source/drain contact of the adjacent transistor across the trench isolation structure. This layout and structure enables further scaling of active region pitches, increased density of transistor formation, better coverage of source/drain silicides by source/drain contact regions, reduced time-dependent dielectric breakdown, and overall better device performance. Embodiments of the present disclosure further provide better functioning integrated circuits and increased wafer yields.

In some embodiments, a method includes forming a first semiconductor fin extending in a first lateral direction, forming a second semiconductor fin extending in the first lateral direction, depositing a trench isolation structure between the first semiconductor fin and the second semiconductor fin, and depositing a gate metal extending in a second lateral direction transverse to the first lateral direction across the first semiconductor fin, the second semiconductor fin, and the trench isolation structure. The method includes growing a first source/drain region of a first transistor on the first semiconductor fin extending partially over the first trench isolation structure, growing a second source/drain region of a second transistor on the second semiconductor fin extending partially over the trench isolation structure, forming, by depositing a first metal layer, a first portion of a first source/drain contact on the first source/drain region and a second source/drain contact on the second source/drain region, and forming, by depositing a second metal layer, a second portion of the first source/drain contact on a top surface of the first portion and extending laterally beyond an edge of the first portion over the trench isolation structure.

In some embodiments, a metho includes depositing a trench isolation structure between a first semiconductor fin and a second semiconductor fin, growing a first source/drain region of a first transistor in a first trench in the first semiconductor fin, growing a second source/drain region of the first transistor in a second trench in the first semiconductor fin, and depositing a first source/drain contact on the first source/drain region of the first transistor. The method includes depositing a second source/drain contact on the second source/drain region of the first transistor. The first source/drain contact has a greater height that the second source/drain contact. The method includes depositing an interlevel dielectric layer over the first transistor, forming a first conductive via in the interlevel dielectric region contacting a top surface of the first source/drain contact, and forming a second conductive via in the interlevel dielectric region contacting a top surface of the second source/drain contact. A height of the first conductive via is less than a height of the second conductive via.

In some embodiments, an integrated circuit includes a first active region extending in a first lateral direction, a second active region extending in the first lateral direction, a trench isolation structure between the first active region and the second active region, and a first transistor. The first transistor includes a first source/drain region in the first semiconductor fin and partially overhanging the trench isolation structure and a first source/drain contact on the first source/drain region and including a first metal structure and a second structure covering at least a portion of a top surface of the first metal structure and extending over a lateral edge of the first portion. The integrated circuit includes a second transistor including a second source/drain region in the second semiconductor fin and partially overlaying the trench isolation structure adjacent to the first source/drain region and a second source/drain contact on the second source/drain region. The integrated circuit includes an interlevel dielectric layer on the first and second source/drain contacts, a first conductive via in the interlevel dielectric layer in contact with a top surface of the second metal structure of the first source/drain contact, and a second conductive via in the interlevel dielectric layer in contact with a top surface of the second source/drain contact. A height of the second conductive via is greater than a height of the first conductive via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor fin extending in a first lateral direction;
forming a second semiconductor fin extending in the first lateral direction;
depositing a trench isolation structure between the first semiconductor fin and the second semiconductor fin;
depositing a gate metal extending in a second lateral direction transverse to the first lateral direction across the first semiconductor fin, the second semiconductor fin, and the trench isolation structure;
growing a first source/drain region of a first transistor on the first semiconductor fin and extending partially over the first trench isolation structure;
growing a second source/drain region of a second transistor on the second semiconductor fin extending partially over the trench isolation structure;
forming, by depositing a first metal layer, a first portion of a first source/drain contact on the first source/drain region and a second source/drain contact on the second source/drain region; and
forming, by depositing a second metal layer, a second portion of the first source/drain contact on a top surface of the first portion and extending laterally beyond an edge of the first portion over the trench isolation structure.

2. The method of claim 1, further comprising:
forming an interlevel dielectric layer over the first source/drain contact and the second source/drain contact; and
forming, with a deposition process, a first conductive via extending through the interlevel dielectric layer and contacting a top surface of the second portion of the first source/drain contact; and
forming, with the deposition process, a second conductive via extending through the interlevel dielectric layer and contacting a top surface of the second source/drain contact, wherein a top surface of the first portion of the source/drain contact is coplanar with a top surface of the second source/drain contact.

3. The method of claim 2, further comprising forming, with the deposition process, a third conductive via contact extending through the interlevel dielectric layer and contacting a top surface of the gate metal.

4. The method of claim 2, wherein the first conductive via is positioned above the edge of the first portion of the first source/drain contact.

5. The method of claim 1, wherein a top surface of first portion of the first source/drain contact is higher than a top surface of the gate metal.

6. The method of claim 1, further comprising electrically isolating the first portion of the first source/drain contact from the second source/drain contact by performing a CMP process.

7. The method of claim 1, further comprising forming an interlevel dielectric layer over the first portion of the first source/drain contact and the second source/drain contact prior to forming the second portion of the first source/drain contact.

8. The method of claim 7, wherein forming the second portion of the first source/drain contact includes:
exposing the top surface of the first portion of the first source/drain contact by forming a trench through the interlevel dielectric layer; and
depositing the second portion of the first source/drain contact in the trench.

9. The method of claim 8, wherein the second portion of the first source/drain contact includes a supply voltage rail.

10. The method of claim 1, wherein the first transistor include:
a plurality of stacked channels;
a plurality of inner spacers interleaved with the stacked channels, wherein the gate metal is wrapped around the channels.

11. A method, comprising:
depositing a trench isolation structure between a first semiconductor fin and a second semiconductor fin;
growing a first source/drain region of a first transistor in a first trench in the first semiconductor fin;
growing a second source/drain region of the first transistor in a second trench in the first semiconductor fin;
depositing a first source/drain contact on the first source/drain region of the first transistor;
depositing a second source/drain contact on the second source/drain region of the first transistor, wherein the first source/drain contact has a greater height that the second source/drain contact;
depositing an interlevel dielectric layer over the first transistor;
forming a first conductive via in the interlevel dielectric region contacting a top surface of the first source/drain contact; and
forming a second conductive via in the interlevel dielectric region contacting a top surface of the second source/drain contact, wherein a height of the first conductive via is less than a height of the second conductive via.

12. The method of claim 11, wherein forming the first source/drain contact includes:
forming a third source/drain region of a second transistor and a fourth source/drain region of the second transistor on the second semiconductor fin, wherein the third source/drain region is spaced apart from the first source/drain region and a second lateral direction across the trench isolation structure, wherein the fourth source/drain region is spaced apart from the second in the second lateral direction across the trench isolation structure;
forming a third source/drain contact on the third source/drain region of the second transistor; and
forming a fourth source/drain contact on the fourth source/drain region of the second transistor, wherein the first source/drain contact has a greater height than the second source/drain contact, wherein the first source/drain contact is closer to the second source/drain contact and the second direction than the second source/drain region is to the fourth source/drain region in the second direction.

13. The method of claim 11, further comprising forming the first source/drain contact with a larger number of metal layers than the second source/drain contact.

14. An integrated circuit, comprising:
a first active region extending in a first lateral direction;
a second active region extending in the first lateral direction;
a trench isolation structure between the first active region and the second active region;
a first transistor including:
a first source/drain region in the first active region and partially overhanging the trench isolation structure; and
a first source/drain contact on the first source/drain region and including a first metal structure and a second metal structure covering at least a portion of a top surface of the first metal structure and extending over a lateral edge of the first portion;
a second transistor including:
a second source/drain region in the second active region partially overhanging the trench isolation structure adjacent to the first source/drain region; and
a second source/drain contact on the second source/drain region;
an interlevel dielectric layer on the first and second source/drain contacts;
a first conductive via in the interlevel dielectric layer in contact with a top surface of the second metal structure of the first source/drain contact; and
a second conductive via in the interlevel dielectric layer in contact with a top surface of the second source/drain contact, wherein a height of the second conductive via is greater than a height of the first conductive via.

15. The integrated circuit of claim 14, wherein the first transistor includes a plurality of stacked channels in contact with the first source/drain region.

16. The integrated circuit of claim 15, wherein the first transistor include a gate metal wrapped around the stacked channels.

17. The integrated circuit of claim 15, wherein a top surface of the gate metal is lower than a top surface of the second source/drain contact.

18. The integrated circuit of claim 14, further comprising a silicide covering an entirety of a top surface of the first source/drain region and an entirety of a top surface of the second source/drain region.

19. The integrated circuit of claim 11, wherein the second portion of the first source/drain contact includes a supply voltage rail.

20. The integrated circuit of claim 14, wherein the second source/drain contact is closer to the second metal structure than to the first metal structure.
